(19) United States
(12) Patent Application Publication
(10) Pub. No.: US 2015/0340211 A1
(43) Pub. Date: Nov. 26, 2015

(54) MAGNETIC-FIELD-GENERATING APPARATUS FOR MAGNETRON SPUTTERING

(71) Applicant: HITACHI METALS, LTD., Minato-ku, Tokyo (JP)

(72) Inventor: Yoshihiko KURIYAMA, Takasaki-shi (JP)

(73) Assignee: HITACHI METALS, LTD., Minato-ku,Tokyo (JP)

(21) Appl. No.: 14/758,624

(22) PCT Filed: Jan. 23, 2014
(86) PCT No.: PCT/JP2014/051380

§ 371 Date: Jun. 30, 2015

(30) Foreign Application Priority Data
Feb. 15, 2013 (JP) 2013-027970

(51) Int. Cl. H01J 37/34; H01F 7/02

(52) U.S. Cl. CPC H01J 37/3405; H01F 7/0205

(57) ABSTRACT

A racetrack-shaped magnetic-field-generating apparatus for magnetron sputtering comprising a straight portion and corner portions, which comprises, on a non-magnetic base, (a) a straight center magnetic pole member; (b) a peripheral magnetic pole member surrounding the center magnetic pole member; (c) pluralities of vertical permanent magnets arranged between the center magnetic pole member and the peripheral magnetic pole member, which are magnetized in a perpendicular direction to the target surface; and (d) pluralities of first and second horizontal permanent magnets arranged on both sides thereof, which are magnetized in parallel to a target surface; the magnetic poles of the first and second horizontal permanent magnets opposing the vertical permanent magnets being the same in polarity as those of the vertical permanent magnets opposing the target surface.

### FIELD OF THE INVENTION

The present invention relates to a magnetic-field-generating apparatus assembled in a magnetron sputtering apparatus forming a thin film on a substrate surface.

### BACKGROUND OF THE INVENTION

Sputtering is a phenomenon that atoms or molecules are projected from a target, against which an inactive material such as Ar, etc. impinges at a high speed, and that the projected atoms or molecules are attached to a substrate to form a thin film. A magnetron sputtering method uses a magnetic field in a cathode to accelerate an accumulating speed of a target material on a substrate, forming a thin film at a low temperature because of no collision of electrons to the substrate. Accordingly, the magnetron sputtering method is widely used to form thin films on substrates in the production of electronic devices such as semiconductor ICs, flat panel displays and solar cells, reflection films, etc.

A magnetron sputtering apparatus comprises, in a vacuum chamber, a substrate on the anode, a target (cathode) opposing the substrate, and a magnetic-field-generating apparatus arranged under the target. Voltage applied between the anode and the cathode causes glow discharge, ionizing an inert gas (for example, Ar gas at about 0.1 Pa) in the vacuum chamber, and secondary electrons discharged from the target are captured by a magnetic field generated by the magnetic-field-generating apparatus to cause a cycloidal motion on the target surface. The cycloidal motion of electrons accelerates the ionization of Ar molecules, resulting in a drastically increased film-forming speed than without a magnetic field, with larger film adhesion strength.

JP 2008-156735 A discloses, as shown in FIGS. 15(a) and 15(b), a magnetic-field-generating apparatus 200 for magnetron sputtering comprising a non-magnetic base 210, a rod-shaped, center magnetic pole member 220 arranged on the non-magnetic base 210, an oval, peripheral magnetic pole member 230 arranged around the center magnetic pole member 220, and pluralities of permanent magnets 240, 250 arranged between the center magnetic pole member and the peripheral magnetic pole member; the permanent magnets 240, 250 being magnetized in a horizontal direction and arranged with their magnetic poles of the same polarity opposing the center magnetic pole member; and the center magnetic pole member and the peripheral magnetic pole member being not lower than the permanent magnets. JP 2008-156735 A describes that this magnetic-field-generating apparatus provides a region of a magnetic field having necessary intensity for containing a plasma-state inert gas (horizontal component of magnetic flux density: 10 mT or more) expanding particularly in corner portions, resulting in an expanded erosion region in the corner portions, thereby making erosion in the straight and corner portions more uniform.

However, because this magnetic-field-generating apparatus generates a magnetic field having a lower magnetic flux density in a region opposing the center magnetic pole member than in other regions, the erosion of a target is slow in a center portion opposing the center magnetic pole member. To improve the use efficiency of a target, it is desired to develop a technology for making a magnetic flux density distribution uniform on the target, thereby relatively accelerating erosion in a target portion opposing the center magnetic pole member.

JP 7-74439 B discloses a magnetron sputtering apparatus comprising an inner magnetic pole, an outer magnetic pole having an opposite polarity and surrounding the inner magnetic pole, and a target arranged on both magnetic poles from the inner magnetic pole to near the outer magnetic pole; both magnetic poles being constituted by permanent magnets having vertical magnetization, or soft-magnetic bodies; permanent magnets having horizontal magnetization being arranged between both magnetic poles; and permanent magnets having opposite horizontal magnetization being arranged outside the outer magnetic pole. JP 7-74439 B describes that plasma can be stably kept on the target, while preventing local erosion on the target, thereby extremely elongating the target life.

However, the magnetron sputtering apparatus described in JP 7-74439 B has a structure comprising permanent magnets extending outside the target (outside the outer magnetic pole) to prevent the local erosion of the target, the magnetic-field-generating apparatus is inevitably large, suffering cost increase.

### OBJECT OF THE INVENTION

Accordingly, an object of the present invention is to provide a magnetic-field-generating apparatus for magnetron sputtering, which provides a uniform magnetic flux density distribution on a target by relatively accelerating erosion in a target portion opposing a center magnetic pole member, thereby improving the use efficiency of a target.

### SUMMARY OF THE INVENTION

As a result of intensive research in view of the above object, the inventor has found that in a magnetic-field-generating apparatus for magnetron sputtering comprising pluralities of permanent magnets magnetized in parallel to a target surface, in a racetrack-shaped region defined by a straight center magnetic pole member and a peripheral magnetic pole member, the replacement of the above permanent magnets by magnet units comprising pluralities of permanent magnets magnetized in a perpendicular direction to the target surface and pluralities of permanent magnets magnetized in parallel to the target surface and arranged on both sides thereof reduces a vertical component of a magnetic flux density (perpendicular to the target surface) on the target surface opposing the center magnetic pole member, thereby relatively accelerating erosion in a target portion opposing the center magnetic pole member. The present invention has been completed based on such finding.

Thus, the magnetic-field-generating apparatus of the present invention for generating a magnetic field on a target surface for magnetron sputtering, which has a racetrack shape comprising a straight portion and corner portions and opposes a target, comprises, on a non-magnetic base,

(a) a straight center magnetic pole member;

(b) a peripheral magnetic pole member surrounding the center magnetic pole member;

(c) pluralities of vertical permanent magnets arranged between the center magnetic pole member and the peripheral magnetic pole member, such that they surround the center magnetic pole member, with their magnetization directions perpendicular to the target surface;

(d) pluralities of first horizontal permanent magnets arranged between the center magnetic pole member and the vertical permanent magnets, their magnetic poles of the first polarity opposing the center magnetic pole member, and their magnetic poles of the second polarity opposing the vertical permanent magnets; and

(e) pluralities of second horizontal permanent magnets arranged between the peripheral magnetic pole member and the vertical permanent magnets, their magnetic poles of the first polarity opposing the peripheral magnetic pole member, and their magnetic poles of the second polarity opposing the vertical permanent magnets;

the magnetic poles of the first and second horizontal permanent magnets opposing the vertical permanent magnets being the same in polarity as those of the vertical permanent magnets opposing the target surface.

The total length of the first and second horizontal permanent magnets in a magnetization direction is preferably 50-95% of a gap between the center magnetic pole member and the peripheral magnetic pole member.

It is preferable that the first and second horizontal permanent magnets have the same thickness in a direction perpendicular to the target surface, and that assuming that their thickness is 100, the thickness of the vertical permanent magnets is 0-150 in a direction perpendicular to the target surface.

The vertical permanent magnets and the first and second horizontal permanent magnets in the corner portions are preferably as thick as 30-100% in a direction perpendicular to the target surface, relative to the vertical permanent magnets and the first and second horizontal permanent magnets, respectively, in the straight portion.

In the corner portions, the second horizontal permanent magnets are preferably thinner than the first horizontal permanent magnets in a direction perpendicular to the target surface.

In the corner portions, the vertical permanent magnets and the first and second horizontal permanent magnets preferably occupy 30% or more by area of a gap between the center magnetic pole member and the peripheral magnetic pole member, when viewed from above.

In the corner portions, the gap between the center magnetic pole member and the peripheral magnetic pole member may be filled with the vertical permanent magnets, the first and second horizontal permanent magnets, and non-magnetic spacers.

The magnetic-field-generating apparatus for magnetron sputtering may be constituted by removing part or all of end portions of the center magnetic pole member, the peripheral magnetic pole member and the vertical permanent magnets, in the corner portions.

Another magnetic-field-generating apparatus of the present invention for magnetron sputtering comprises, on a non-magnetic base,

(a) a straight center magnetic pole member;

(b) a peripheral magnetic pole member surrounding the center magnetic pole member;

(c) an intermediate magnetic pole member arranged between the center magnetic pole member and the peripheral magnetic pole member, such that they surround the center magnetic pole member;

(d) pluralities of first horizontal permanent magnets arranged between the center magnetic pole member and the intermediate magnetic pole member, their magnetic poles of the first polarity opposing the center magnetic pole member, and their magnetic poles of the second polarity opposing the intermediate magnetic pole member; and

(e) pluralities of second horizontal permanent magnets arranged between the peripheral magnetic pole member and the intermediate magnetic pole member, their magnetic poles of the first polarity opposing the peripheral magnetic pole member, and their magnetic poles of the second polarity opposing the intermediate magnetic pole member;

the magnetic poles of the first and second horizontal permanent magnets opposing the intermediate magnetic pole member having the same polarity.

The intermediate magnetic pole member preferably has width, which is 10-75% of the thickness of the first and second horizontal permanent magnets in a direction perpendicular to the target surface.

It is preferable that the first and second horizontal permanent magnets have the same thickness in a direction perpendicular to the target surface, and that assuming that their thickness is 100, the thickness of the intermediate magnetic pole member is 0-150 in a direction perpendicular to the target surface.

The magnetic-field-generating apparatus for magnetron sputtering may be constituted by removing part or all of end portions of the center magnetic pole member, the peripheral magnetic pole member and the intermediate magnetic pole member, in the corner portions.

When a magnetic field applied to the target surface is measured in a direction perpendicular to the axial direction in the straight portion, the maximum magnetic flux density in parallel to the target surface is preferably larger than a magnetic flux density in a perpendicular direction to the target surface, in a region opposing the center magnetic pole member.

At a position where a magnetic field applied to the target surface has a magnetic flux density of zero in a perpendicular direction to the target surface, a magnetic flux density in parallel to the target surface is preferably 10 mT or more.

### BRIEF DESCRIPTION OF THE DRAWINGS

FIG. 1(a) is a plan view showing an example of the magnetic-field-generating apparatuses of the present invention for magnetron sputtering.

FIG. 1(b) is a cross-sectional view taken along the line A-A in FIG. 1(a).

FIG. 1(c) is a cross-sectional view taken along the line B-B in FIG. 1(a).

FIG. 2(a) is a plan view showing another example of the magnetic-field-generating apparatuses of the present invention for magnetron sputtering.

FIG. 2(b) is a cross-sectional view taken along the line C-C in FIG. 2(a).

FIG. 2(c) is a cross-sectional view taken along the line D-D in FIG. 2(a).

FIG. 3(a) is a plan view showing a further example of the magnetic-field-generating apparatuses of the present invention for magnetron sputtering.

FIG. 3(b) is a cross-sectional view taken along the line E-E in FIG. 3(a).

FIG. 3(c) is a cross-sectional view taken along the line F-F in FIG. 3(a).

FIG. 4(a) is a plan view showing a still further example of the magnetic-field-generating apparatuses of the present invention for magnetron sputtering.

FIG. 4(b) is a cross-sectional view taken along the line G-G in FIG. 4(a).

FIG. 4(c) is a cross-sectional view taken along the line H-H in FIG. 4(a).

FIG. 5(a) is a plan view showing a still further example of the magnetic-field-generating apparatuses of the present invention for magnetron sputtering.

FIG. 5(b) is a cross-sectional view taken along the line I-I in FIG. 5(a).

FIG. 5(c) is a cross-sectional view taken along the line J-J in FIG. 5(a).

FIG. 6(a) is a plan view showing a still further example of the magnetic-field-generating apparatuses of the present invention for magnetron sputtering.

FIG. 6(b) is a cross-sectional view taken along the line K-K in FIG. 6(a).

FIG. 6(c) is a cross-sectional view taken along the line L-L in FIG. 6(a).

FIG. 7 is a cross-sectional view showing another example of magnets for corner portions in the magnetic-field-generating apparatus of the present invention for magnetron sputtering.

FIG. 8 is a plan view showing a further example of corner portions in the magnetic-field-generating apparatus of the present invention for magnetron sputtering.

FIG. 9 is a plan view showing a still further example of corner portions in the magnetic-field-generating apparatus of the present invention for magnetron sputtering.

FIG. 10(a) is a plan view showing the magnetic-field-generating apparatus of Example 1.

FIG. 10(b) is a cross-sectional view taken along the line M-M in FIG. 10(a).

FIG. 11(a) is a plan view showing the magnetic-field-generating apparatus of Comparative Example 1.

FIG. 11(b) is a cross-sectional view taken along the line N-N in FIG. 11(a).

FIG. 12(a) is a schematic view showing lines A, B, C and D in the magnetic-field-generating apparatus of Example 1.

FIG. 12(b) is a schematic view showing lines A, B, C and D in the magnetic-field-generating apparatus of Comparative Example 1.

FIG. 13 is a graph showing parallel and vertical components of a magnetic flux density generated on a target surface by the magnetic-field-generating apparatus of Example 1, which are plotted along the lines A, B, C and D.

FIG. 14 is a graph showing parallel and vertical components of a magnetic flux density generated on a target surface by the magnetic-field-generating apparatus of Comparative Example 1, which are plotted along the lines A, B, C and D.

FIG. 15(a) is a plan view showing an example of conventional magnetic-field-generating apparatuses for magnetron sputtering.

FIG. 15(b) is a cross-sectional view taken along the line O-O in FIG. 15(a).

### DESCRIPTION OF THE PREFERRED EMBODIMENTS

### [1] Magnetic-Field-Generating Apparatus for Magnetron Sputtering

(A) Overall Structure

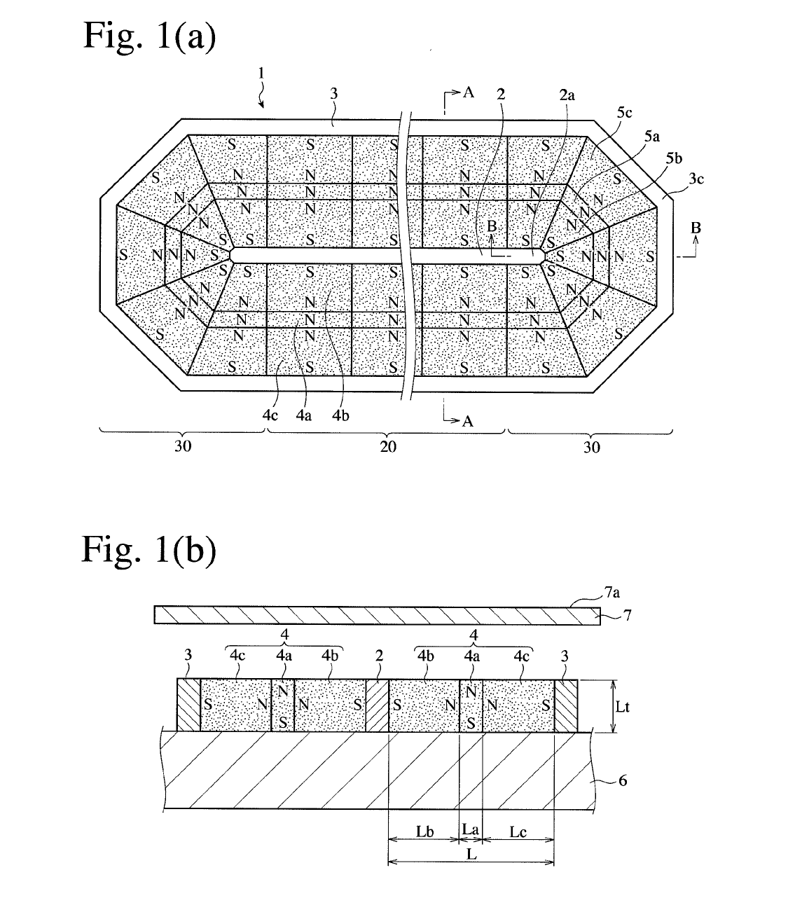

As shown in FIGS. 1(a), 1(b) and 1(c), for example, the magnetic-field-generating apparatus of the present invention for magnetron sputtering is in a racetrack shape comprising a straight portion 20 and two corner portions 30, 30 opposing a target 7 for generating a racetrack-shaped magnetic field on the target surface.

(1) First Structure

The first magnetic-field-generating apparatus 1 for magnetron sputtering comprises, on a non-magnetic base 6,

(a) a straight center magnetic pole member 2;

(b) a peripheral magnetic pole member 3 surrounding the center magnetic pole member 2;

(c) pluralities of vertical permanent magnets 4a, 5a arranged between the center magnetic pole member 2 and the peripheral magnetic pole member 3 and surrounding the center magnetic pole member 2, with their magnetization directions perpendicular to the target surface 7a;

(d) pluralities of first horizontal permanent magnets 4b, 5b arranged between the center magnetic pole member 2 and the vertical permanent magnets 4a, 5a, their magnetic poles of the first polarity opposing the center magnetic pole member 2, and their magnetic poles of the second polarity opposing the vertical permanent magnets 4a, 5a; and

(e) pluralities of second horizontal permanent magnets 4c, 5c arranged between the peripheral magnetic pole member 3 and the vertical permanent magnets 4a, 5a, their magnetic poles of the first polarity opposing the peripheral magnetic pole member 3, and their magnetic poles of the second polarity opposing the vertical permanent magnets 4a, 5a;

the magnetic poles of the first horizontal permanent magnets 4b, 5b and the second horizontal permanent magnets 4c, 5c opposing the vertical permanent magnets 4a, 5a being the same in polarity as those of the vertical permanent magnets 4a, 5a opposing the target surface 7a.

(i) Structure of Straight Portion

As shown in FIGS. 1(a) and 1(b), for example, the straight portion 20 comprises, on a non-magnetic base 6,

(a) a quadrangular-prism-shaped center magnetic pole member 2;

(b) two quadrangular-prism-shaped peripheral magnetic pole members 3 arranged on both sides of the center magnetic pole member 2, such that they are in parallel with and separate from the center magnetic pole member 2;

(c) pluralities of vertical permanent magnets 4a each in a rectangular shape when viewed from above, which are arranged adjacently to each other between the center magnetic pole member 2 and the peripheral magnetic pole member 3 in parallel therewith, their magnetization directions being perpendicular to the target surface 7a, and their magnetic poles of the same polarity (N poles in the figure) opposing the target surface 7a;

(d) pluralities of first horizontal permanent magnets 4b in a rectangular shape when viewed from above, which are arranged between the center magnetic pole member 2 and the vertical permanent magnets 4a, their magnetization directions being in parallel with the target surface 7a, their magnetic poles of the first polarity (S poles in the figure) opposing the center magnetic pole member 2, and their magnetic poles of the second polarity (N poles in the figure) opposing the vertical permanent magnets 4a; and

(e) pluralities of second horizontal permanent magnets 4c in a rectangular shape when viewed from above, which are arranged between the peripheral magnetic pole member 3 and the vertical permanent magnets 4a, their magnetization directions being in parallel with the target surface 7a, their magnetic poles of the first polarity (S poles in the figure) opposing the peripheral magnetic pole member 3, and their magnetic poles of the second polarity (N poles in the figure) opposing the vertical permanent magnets 4a;

the magnetic poles (N poles in the figure) of the first horizontal permanent magnets 4b and the second horizontal permanent magnets 4c opposing the vertical permanent magnets 4a being the same in polarity as the magnetic poles (N poles in the figure) of the vertical permanent magnets 4a opposing the target surface.

In the straight portion 20, permanent magnets units 4 each constituted by a vertical permanent magnet 4a, a first horizontal permanent magnet 4b and a second horizontal permanent magnet 4c arranged adjacently to each other fill a gap between the center magnetic pole member 2 and the peripheral magnetic pole member 3. In each permanent magnet unit 4, the total (Lb+Lc) of the magnetization-direction length Lb of the first horizontal permanent magnet 4b and the magnetization-direction length Lc of the second horizontal permanent magnet 4c is preferably 50-95%, more preferably 80-90%, of the length L of the permanent magnet unit 4 in a direction of arranging these permanent magnets. Accordingly, the arrangement-direction length La of the vertical permanent magnet 4a, which corresponds to the gap between the first horizontal permanent magnet 4b and the second horizontal permanent magnet 4c, is preferably 5-50%, more preferably 10-20%, of the length L. The magnetization-direction length Lb of the first horizontal permanent magnet 4b and the magnetization-direction length Lc of the second horizontal permanent magnet 4c may be different, though they are preferably substantially equal.

The thickness Ltb of the first horizontal permanent magnet 4b is preferably equal to the thickness Ltc of the second horizontal permanent magnet 4c in a direction perpendicular to the target surface 7a. The thickness Lta of the vertical permanent magnet 4a may be the same as or different from the thickness Ltb and the thickness Ltc, in a direction perpendicular to the target surface 7a. The intensity and distribution of a magnetic field generated can be adjusted by changing the thickness Lta of the vertical permanent magnet 4a in a direction perpendicular to the target surface 7a. The thickness Lta of the vertical permanent magnet 4a in a direction perpendicular to the target surface 7a is preferably 50-150%, more preferably 80-120%, of the thickness Ltb and the thickness Ltc. The thickness Lta need not be the same for all vertical permanent magnets 4a in the straight portion, but may be partially changed depending on purposes.

The vertical permanent magnets 4a, the first horizontal permanent magnets 4b, and the second horizontal permanent magnets 4c may be separately attached to the base 6 with an adhesive, etc., or permanent magnet units 4 each integrally comprising a vertical permanent magnet 4a, a first horizontal permanent magnet 4b, and a second horizontal permanent magnet 4c may be attached to the base 6. Each vertical permanent magnet 4a, each first horizontal permanent magnet 4b, and each second horizontal permanent magnet 4c may be constituted by two or more permanent magnets.

In FIG. 1(a), pluralities of permanent magnet units 4 each comprising a vertical permanent magnet 4a, a first horizontal permanent magnet 4b and a second horizontal permanent magnet 4c are aligned with each other, between the center magnetic pole member 2 and the peripheral magnetic pole member 3, to constitute a magnetic circuit in the straight portion 20, but an integral permanent magnet unit 4 may be used in place of pluralities of permanent magnet units 4, to constitute a magnetic circuit in the straight portion 20. Depending on a necessary magnetic field intensity and a magnet material, pluralities of permanent magnet units 4 may be arranged with gaps to constitute a magnetic circuit in the straight portion 20. When arranged with gaps, gaps between the permanent magnet units 4 may or may not be filled with non-magnetic spacers. The number and size of the permanent magnet units 4 are not particularly restricted, and they may have any sizes, which may be different, from the aspect of easiness of production or assembling.

(ii) Structure of Corner Portions

As shown in FIGS. 1(a) and 1(c), for example, each corner portion 30 comprises

(a) an end portion 2a of the center magnetic pole member 2;

(b) a semipolygonal, peripheral corner magnetic pole member 3c arranged around the end portion 2a of the center magnetic pole member 2;

(c) pluralities of vertical permanent magnets 5a each having a trapezoidal shape when viewed from above, which are arranged adjacently to each other in parallel with the peripheral corner magnetic pole member 3c between the end portion 2a of the center magnetic pole member 2 and the peripheral corner magnetic pole member 3c, their magnetization directions being perpendicular to the target surface 7a, and their magnetic poles of the first polarity (N poles in the figure) opposing the target surface 7a;

(d) pluralities of first horizontal permanent magnets 5b each having a trapezoidal shape when viewed from above, which are arranged with their magnetization directions in parallel with the target surface 7a between the end portion 2a of the center magnetic pole member 2 and the vertical permanent magnets 5a, their magnetic poles of the first polarity (S poles in the figure) opposing the end portion 2a of the center magnetic pole member 2, and their magnetic poles of the second polarity (N poles in the figure) opposing the vertical permanent magnets 5a; and

(e) pluralities of second horizontal permanent magnets 5c each having a trapezoidal shape when viewed from above, which are arranged with their magnetization directions in parallel with the target surface 7a between the peripheral corner magnetic pole member 3c and the vertical permanent magnets 5a, their magnetic poles of the first polarity (S poles in the figure) opposing the peripheral corner magnetic pole member 3c, and their magnetic poles of the second polarity (N poles in the figure) opposing the vertical permanent magnets 5a;

the magnetic poles (N poles in the figure) of the first horizontal permanent magnets 5b and the second horizontal permanent magnets 5c opposing the vertical permanent magnets 5a being the same as the magnetic poles (N poles in the figure) of the vertical permanent magnets 5a opposing the target surface.

The end portion 2a of the center magnetic pole member 2 and the peripheral corner magnetic pole member 3c are semipolygonal in FIG. 1(a), though they may be semicircular. When viewed from above, the vertical permanent magnets 5a, the first horizontal permanent magnets 5b and the second horizontal permanent magnets 5c are trapezoidal in FIG. 1(a), though they may be rectangular.

In each corner portion 30, permanent magnet units 5 each adjacently comprising a vertical permanent magnet 5a, a first horizontal permanent magnet 5b and a second horizontal permanent magnet 5c are arranged in the gap between the end portion 2a of the center magnetic pole member 2 and the peripheral corner magnetic pole member 3c. The structure of each permanent magnet unit 5 may be the same as that of each permanent magnet unit 4 in the straight portion. Namely, in each permanent magnet unit 5, the total (Lb′+Lc′) of the magnetization-direction length Lb′ of the first horizontal permanent magnet 5b and the magnetization-direction length Lc′ of the second horizontal permanent magnet 5c is preferably 50-95%, more preferably 80-90%, of the length L′ of the permanent magnet unit 5 in an arrangement direction. Accordingly, the length La′ of the vertical permanent magnet 5a in the arrangement direction, which corresponds to the gap between the first horizontal permanent magnets 5b and the second horizontal permanent magnets 5c, is preferably 5-50%, more preferably 10-20%, of the length L′. The magnetization-direction length Lb′ of the first horizontal permanent magnet 5b and the magnetization-direction length Lc′ of the second horizontal permanent magnet 5c may be different, though they are preferably substantially equal.

The length L′ of the permanent magnet unit 5, the length La′ of the vertical permanent magnet 5a, the length Lb′ of the first horizontal permanent magnet 5b, and the length Lc′ of the second horizontal permanent magnet 5c may be equal to or different from the lengths L, La, Lb and Lc of corresponding parts in the permanent magnet unit 4, depending on purposes such as the expansion of an erosion region of a target in the corner portions, etc. In this case, too, the arrangement-direction length La′ of the vertical permanent magnet 5a in the corner portions is preferably equal to the arrangement-direction length La of the vertical permanent magnet 4a in the straight portion.

The thickness Ltb′ of the first horizontal permanent magnet 5b is preferably equal to the thickness Ltc′ of the second horizontal permanent magnet 5c, and the thickness Lta′ of the vertical permanent magnet 5a may be the same as or different from the thickness Ltb′ and the thickness Ltc′, in a direction perpendicular to the target surface 7a. The intensity and distribution of a magnetic field generated can be adjusted by changing the thickness Lta′ of the vertical permanent magnet 5a in a direction perpendicular to the target surface 7a. The thickness Lta′ of the vertical permanent magnet 5a in a direction perpendicular to the target surface 7a is preferably 50-150%, more preferably 80-120%, of the thickness Ltb′ and the thickness Ltc′. The thickness Lta′ need not be the same for all vertical permanent magnets 5a in the corner portions, but may be partially different depending on applications.

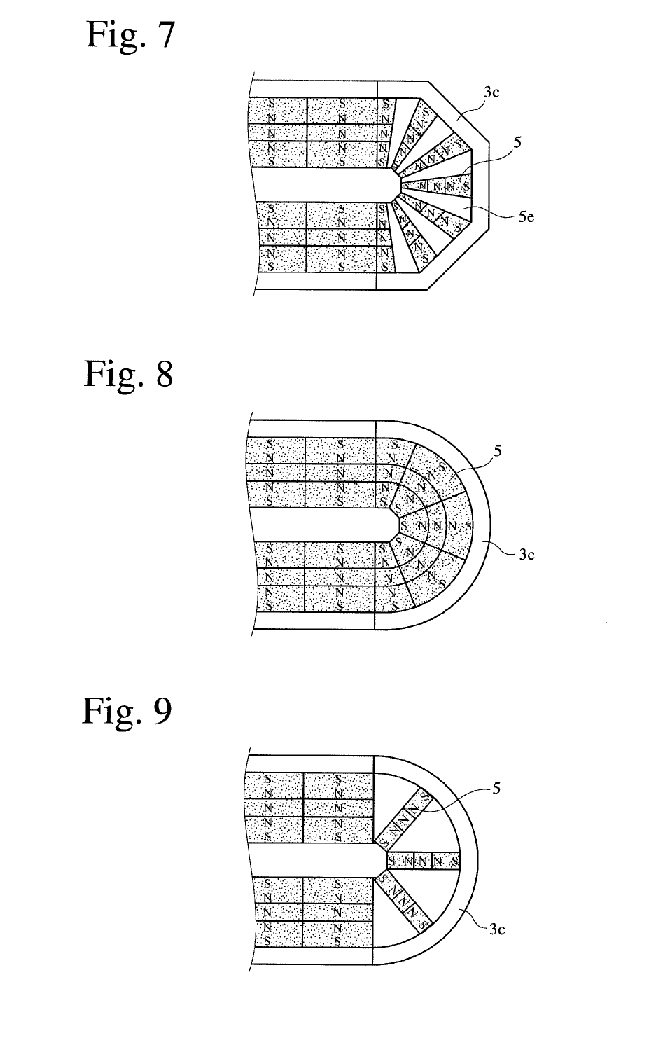

In the corner portions, the permanent magnet units 5 may be arranged to completely fill a gap between the end portion 2a of the center magnetic pole member 2 and the peripheral corner magnetic pole member 3c semipolygonally arranged around it as shown in FIG. 1(a), or the permanent magnet units 5 may be arranged with gaps 5e as shown in FIG. 7. By arranging the permanent magnet units 5 with gaps 5e in the corner portions, a magnetic flux density on the target surface can be adjusted. Each gap 5e may be filled with a non-magnetic spacer. Though not particularly restrictive, the occupation ratio of the permanent magnet units 5 in the gap between the end portion 2a of the center magnetic pole member 2 and the peripheral corner magnetic pole member 3c in each corner portion is preferably 30% or more by area.

The shape of each permanent magnet unit 5 when viewed from above is preferably determined depending on the shape of the peripheral corner magnetic pole member 3c in each corner portion. When the peripheral corner magnetic pole member 3c is semipolygonal in each corner portion as shown in FIG. 7, the shape of each permanent magnet unit 5 is preferably substantially trapezoidal when viewed from above. When the peripheral corner magnetic pole member 3c is semicircular as shown in FIG. 8, it is preferably substantially in a fan shape when viewed from above. As shown in FIG. 9, it may be in a rectangular shape when viewed from above. The number and size of the permanent magnet units 5 in the corner portions are not particularly restricted, but they may have any sizes, which may be different, from the aspect of easiness of production or assembling.

In the corner portions, the vertical permanent magnets 5a, the first horizontal permanent magnets 5b and the second horizontal permanent magnets 5c may be separately attached to the base 6 with an adhesive, etc., or integral permanent magnet units 5 each comprising a vertical permanent magnet 5a, a first horizontal permanent magnet 5b and a second horizontal permanent magnet 5c adhered to each other may be attached to the base 6. Each vertical permanent magnet 5a, each first horizontal permanent magnet 5b, and each second horizontal permanent magnet 5c may be constituted by two or more permanent magnets.

The thickness Lta′ of the vertical permanent magnet 5a, the thickness Ltb′ of the first horizontal permanent magnet 5b, and the thickness Ltc′ of the second horizontal permanent magnet 5c in a direction perpendicular to the target surface 7a may be equal to or different from the lengths Lta, Ltb and Ltc of corresponding parts of the permanent magnet unit 4 in the straight portion, depending on purposes such as the expansion of an erosion region of a target in the corner portions.

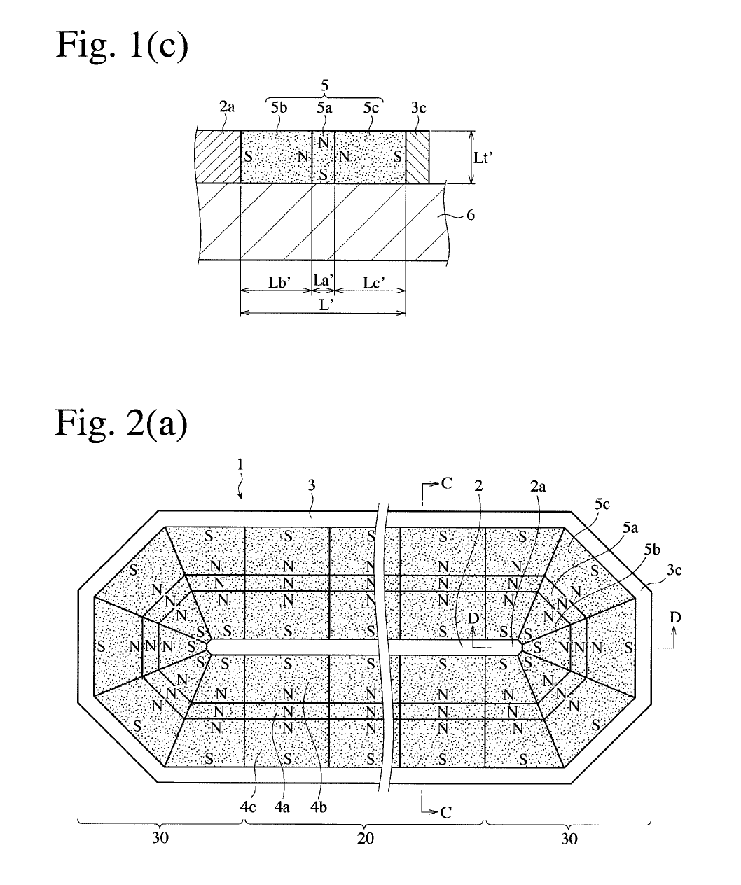

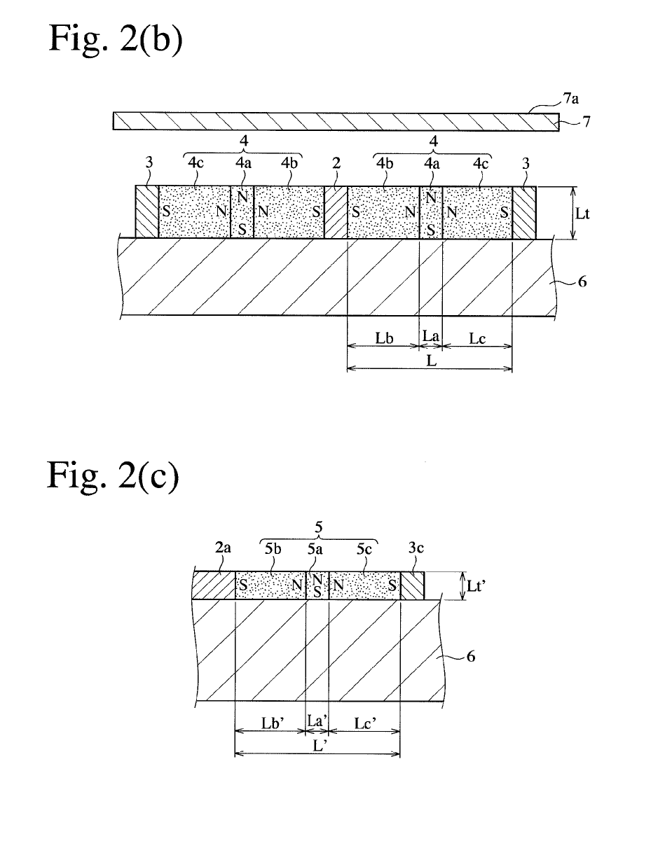

As shown in FIGS. 2(a), 2(b) and 2(c), for example, the thickness Lt′ of the permanent magnet units 5 in the corner portions may be smaller than the thickness Lt of the permanent magnet units 4 in the straight portion, in a direction perpendicular to the target surface 7a. When the permanent magnet units 5 are thinner in the corner portions, the base 6 is preferably thicker in the corner portions 30, to keep a constant distance between the permanent magnet units 5 and the target surface 7a in the corner portions. With such structure, a magnetic flux density on the target surface can be adjusted in the corner portions. The thickness Lt′ of the permanent magnet units 5 may be properly determined in the corner portions, if necessary, but is preferably 30-100% of the thickness Lt of the permanent magnet units 4 in the straight portion.

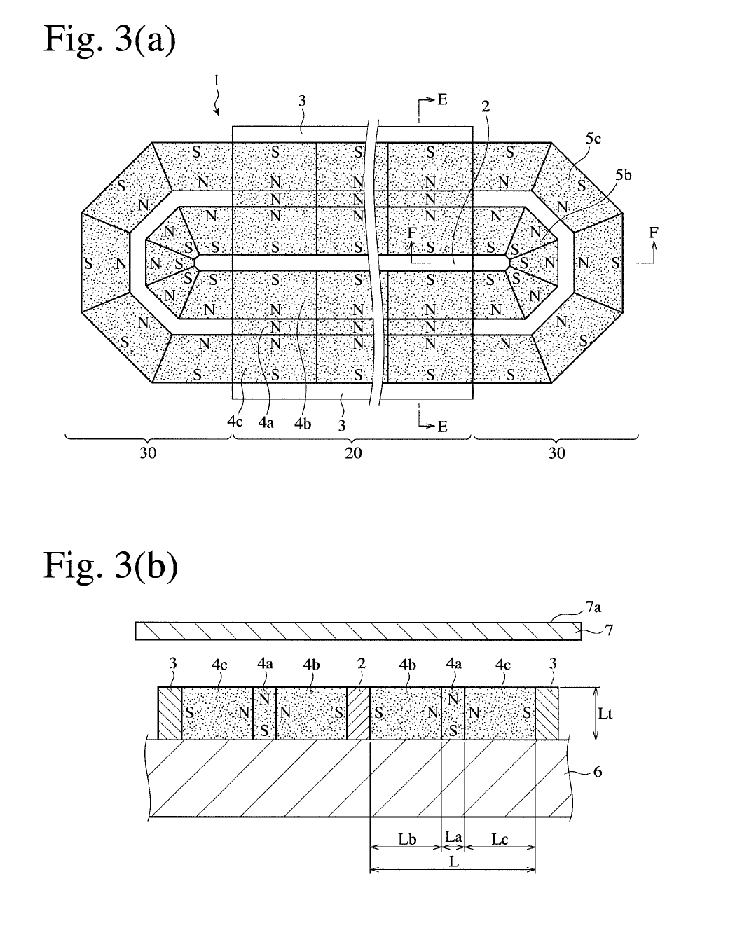

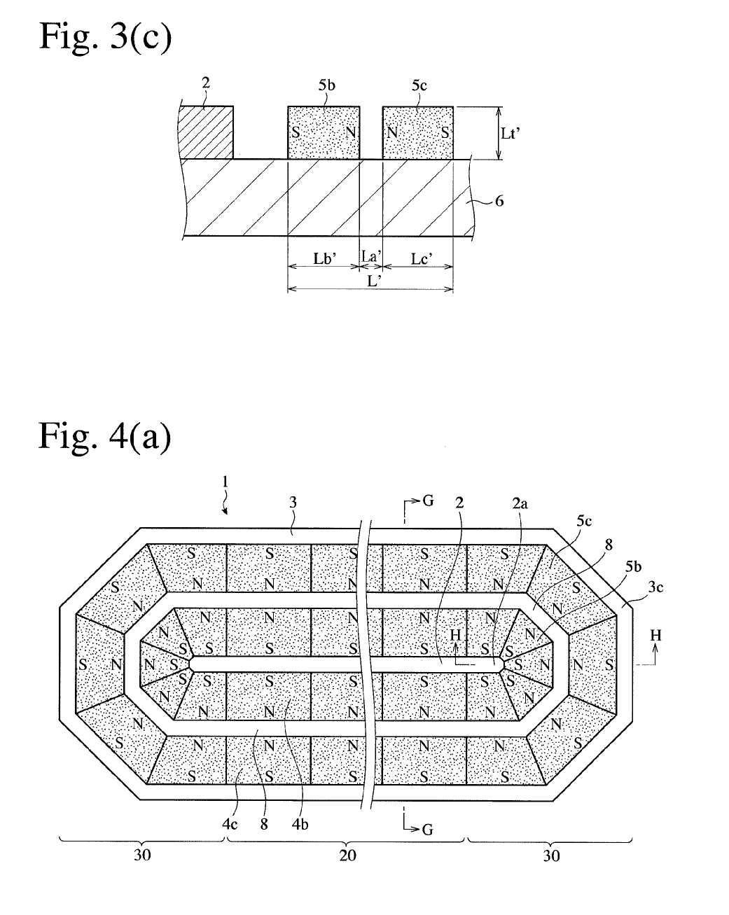

To adjust a magnetic flux density on the target surface, as shown in FIGS. 3(a), 3(b) and 3(c), for example, the end portion 2a of the center magnetic pole member, the peripheral magnetic pole member 3c and the vertical permanent magnets 5a may be removed in the corner portions. The end portion 2a of the center magnetic pole member, the peripheral magnetic pole member 3c and the vertical permanent magnets 5a may be totally or partially removed in the corner portions, to properly adjust a magnetic flux density on the target surface. When partially removed, they are preferably symmetric with respect to a plane along the longitudinal axis of the center magnetic pole member 2 and perpendicular to the target surface, such that both corner portions 30, 30 are symmetric [vertically symmetric in FIG. 3(a)].

(2) Second Structure

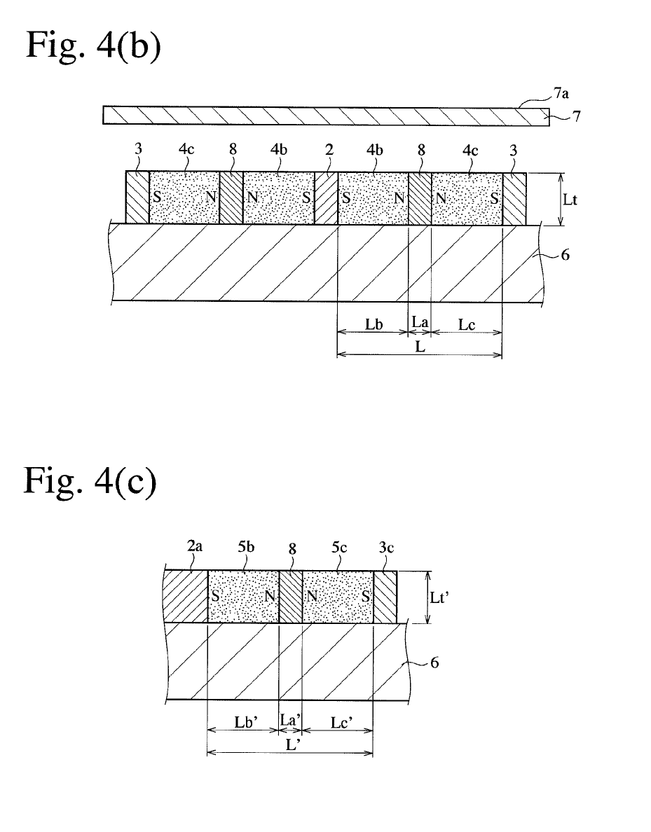

As shown in FIGS. 4(a), 4(b) and 4(c), a magnetic-field-generating apparatus for magnetron sputtering may be constituted by substituting the vertical permanent magnets 4a in the straight portion 20 and the vertical permanent magnets 5a in the corner portions 30 in the first structure by an intermediate magnetic pole member 8 made of a magnetic material (soft-magnetic material). The vertical permanent magnets 4a in the straight portion 20 and the vertical permanent magnets 5a in the corner portions 30 may be totally or partially substituted by the intermediate magnetic pole member 8. Because the second structure is the same as the first structure except that the vertical permanent magnets 4a, 5a are substituted by the intermediate magnetic pole member 8, detailed explanation will be made only on the intermediate magnetic pole member 8 below.

(i) Structure of Straight Portion

In the straight portion 20, the width of the intermediate magnetic pole member 8 is preferably 10-75%, more preferably 20-60%, of the thickness of the first horizontal permanent magnets 4b and the second horizontal permanent magnets 4c in a direction perpendicular to the target surface 7a.

The thickness Lta of the intermediate magnetic pole member 8 may be the same as or different from the thickness Ltb of the first horizontal permanent magnets 4b and the thickness Ltc of the second horizontal permanent magnets 4c, in a direction perpendicular to the target surface 7a. The intensity and distribution of a magnetic field generated can be adjusted by changing the thickness Lta of the intermediate magnetic pole member 8 in a direction perpendicular to the target surface 7a. The thickness Lta of the intermediate magnetic pole member 8 in a direction perpendicular to the target surface 7a is preferably 50-150%, more preferably 80-120%, of the thickness Ltb and the thickness Ltc.

(ii) Structure of Corner Portions

The width of the intermediate magnetic pole member 8 is preferably 10-75%, more preferably 20-60%, of the thickness of the first horizontal permanent magnets 5b and the second horizontal permanent magnets 5c in a direction perpendicular to the target surface 7a.

The thickness Lta′ of the intermediate magnetic pole member 8 may be the same as or different from the thickness Ltb′ of the first horizontal permanent magnets 5b and the thickness Ltc′ of the second horizontal permanent magnets 5c, in a direction perpendicular to the target surface 7a. The intensity and distribution of a magnetic field generated can be adjusted by changing the thickness Lta′ of the intermediate magnetic pole member 8 in a direction perpendicular to the target surface 7a. The thickness Lta′ of the intermediate magnetic pole member 8 in a direction perpendicular to the target surface 7a is preferably 50-150%, more preferably 80-120%, of the thickness Ltb′ and the thickness Ltc′.

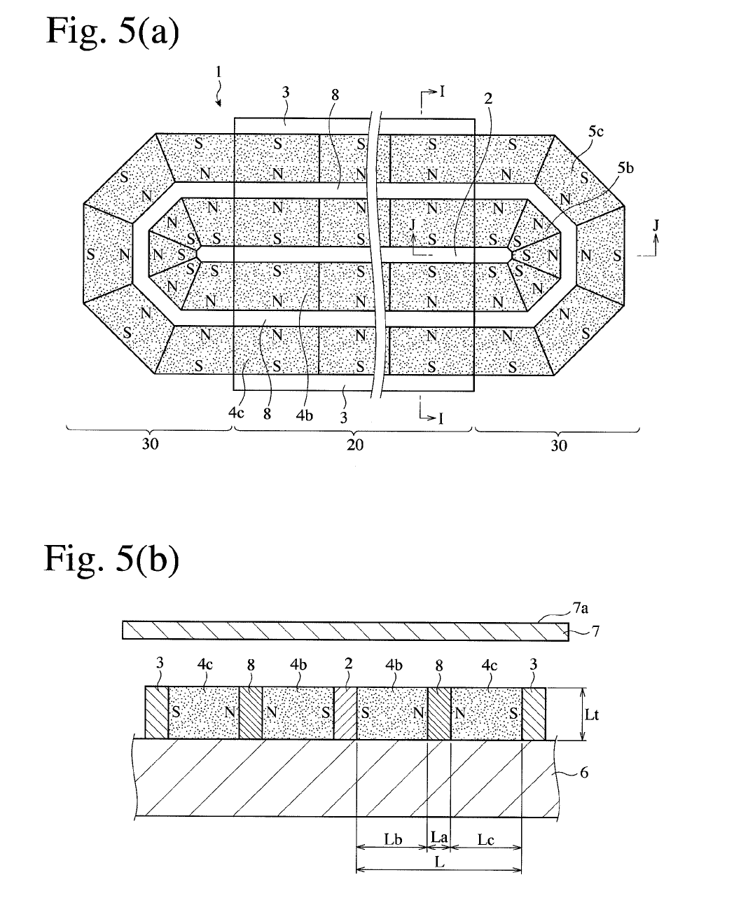

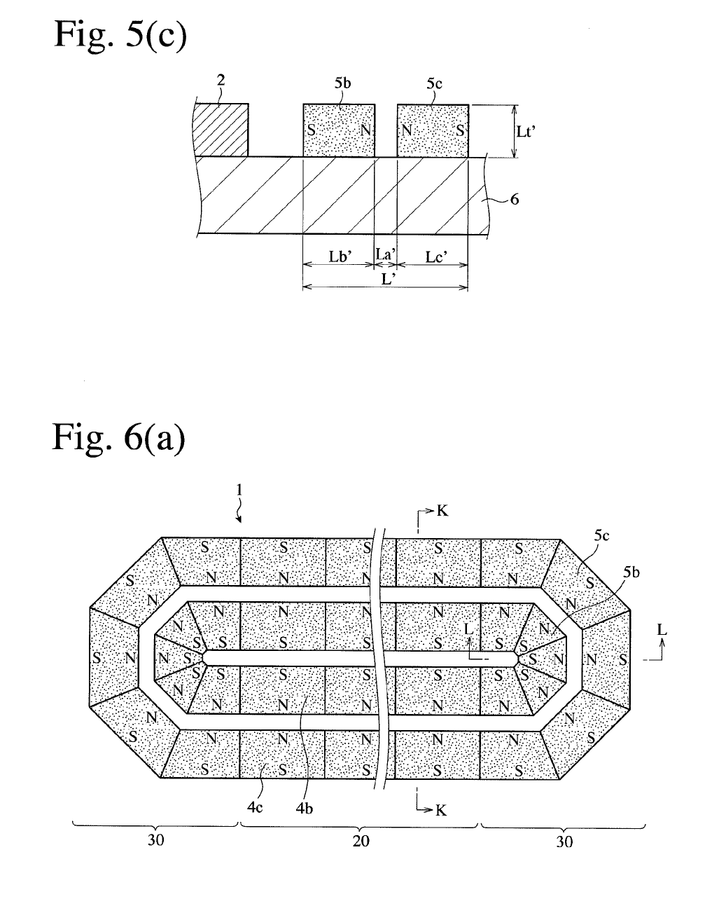

To adjust a magnetic flux density on the target surface, for example, as shown in FIGS. 5(a), 5(b) and 5(c), the end portion 2a of the center magnetic pole member, the peripheral magnetic pole member 3c and the intermediate magnetic pole member 8 may be removed in the corner portions. The end portion 2a of the center magnetic pole member, the peripheral magnetic pole member 3c and the intermediate magnetic pole member 8 may be totally removed in the corner portions, or may be partially removed to properly adjust a magnetic flux density on the target surface. When partially removed, they are preferably symmetric with respect to a plane along the longitudinal axis of the center magnetic pole member 2 and perpendicular to the target surface, such that both corner portions 30, 30 are symmetric [vertically symmetric in FIG. 5(a)].

(3) Third Structure

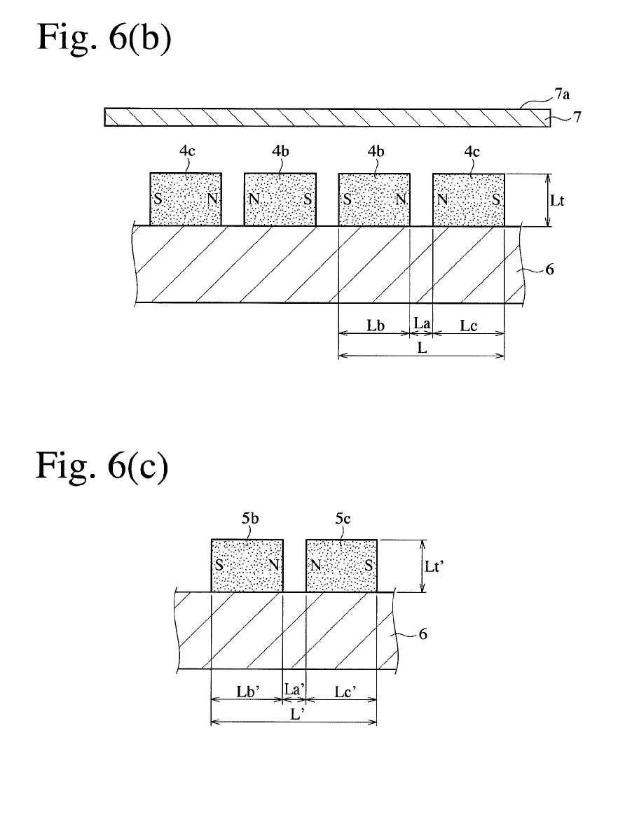

As shown in FIGS. 6(a), 6(b) and 6(c), a magnetic-field-generating apparatus for magnetron sputtering may be constituted by totally removing the center magnetic pole member 2, the peripheral magnetic pole member 3 and the vertical permanent magnets 4a in the straight portion 20, and the end portion 2a of the center magnetic pole member, the peripheral magnetic pole member 3c and the vertical permanent magnets 5a in the corner portions 30 from the first structure.

(B) Permanent Magnets

Permanent magnets in the straight portion and the corner portions may be formed by known permanent magnet materials. Materials for the permanent magnets may be properly determined depending on the structure of an apparatus (distance between a magnetic-field-generating apparatus and a target), and a necessary magnetic field intensity. In the present invention, permanent magnets are preferably selected, such that a parallel component of a magnetic flux density of a magnetic field on the target surface 7a is 10 mT or more, at a position at which a vertical component of the magnetic flux density is zero.

To obtain a high magnetic flux density, rare earth magnets such as anisotropic sintered R-T-B magnets comprising R (at least one of rare earth elements such as Nd), T (Fe or Fe and Co) and B as indispensable components (subjected to various surface treatments for corrosion resistance) may be used. When a necessary magnetic flux density is not so high, ferrite magnets may be used. When different magnetic flux densities should be obtained in the straight portion and the corner portions, the materials and sizes of their permanent magnets may be determined depending on their necessary magnetic flux densities.

(C) Magnetic Pole Members

Known magnetic materials (soft-magnetic materials), particularly magnetic steel, are preferably used for the magnetic pole members.

### [2] Other Embodiments

With pluralities of magnetic-field-generating apparatuses of the present invention arranged in parallel with a predetermined interval, a large substrate can be coated using an integral target. The magnetic-field-generating apparatus may have a mechanism for adjusting the distance between its upper surface and a target surface.

The present invention will be explained in more detail referring to Examples below, without intention of restricting the present invention thereto.

### Example 1

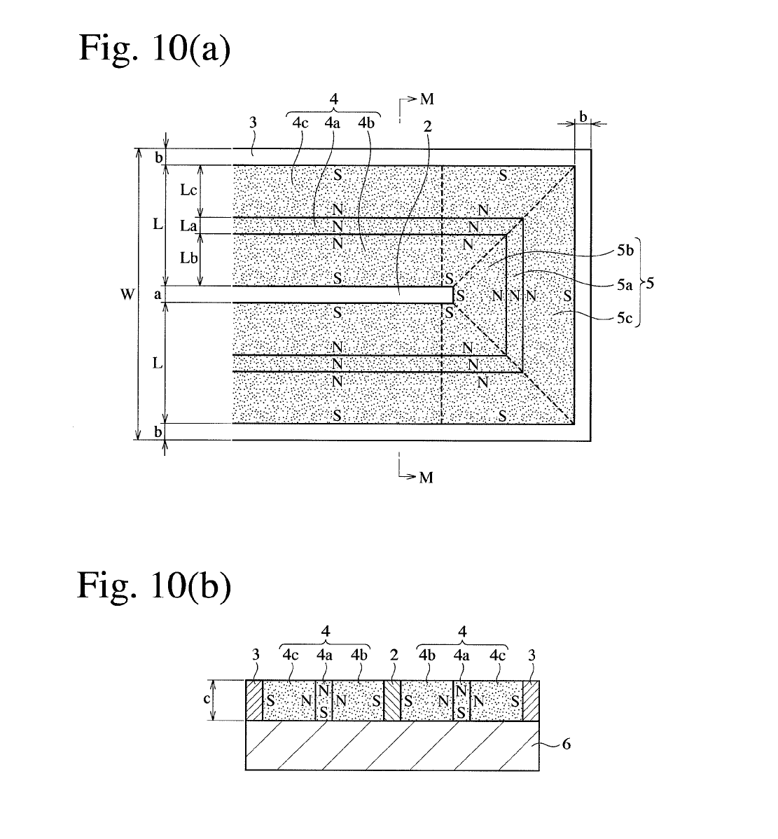

As shown in FIGS. 10(a) and 10(b), a center magnetic pole member 2 and a peripheral magnetic pole member 3 both made of ferritic stainless steel (SUS430), and permanent magnet units 4 (vertical permanent magnets 4a, and first and second horizontal permanent magnets 4b, 4c) for the straight portion and permanent magnet units 5 (vertical permanent magnets 5a, and first and second horizontal permanent magnets 5b, 5c) for the corner portions both made of a sintered ferrite magnet (NMF-12F available from Hitachi Metals, Ltd., residual magnetic flux density: about 450 mT) were arranged on a base 6 made of an Al—Mg alloy (A5052), to produce a magnetic-field-generating apparatus 1 (W=160 mm, L=70 mm, La=10 mm, Lb=30 mm, Lc=30 mm, a=10 mm, b=5 mm, and c=25 mm).

### Comparative Example 1

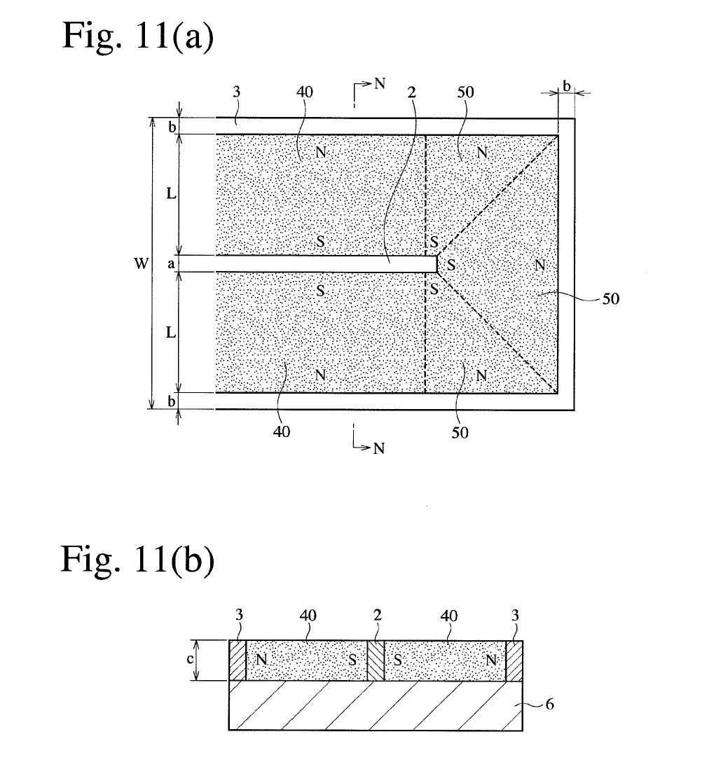

A magnetic-field-generating apparatus 1 (W=170 mm, L=75 mm, a=10 mm, b=5 mm, and c=25 mm) was produced in the same manner as in Example 1, except for changing the permanent magnet units 4 for the straight portion and the permanent magnet units 5 for the corner portions respectively to permanent magnets 40 for the straight portion and permanent magnets 50 for the corner portions as shown in FIGS. 11(a) and 11(b).

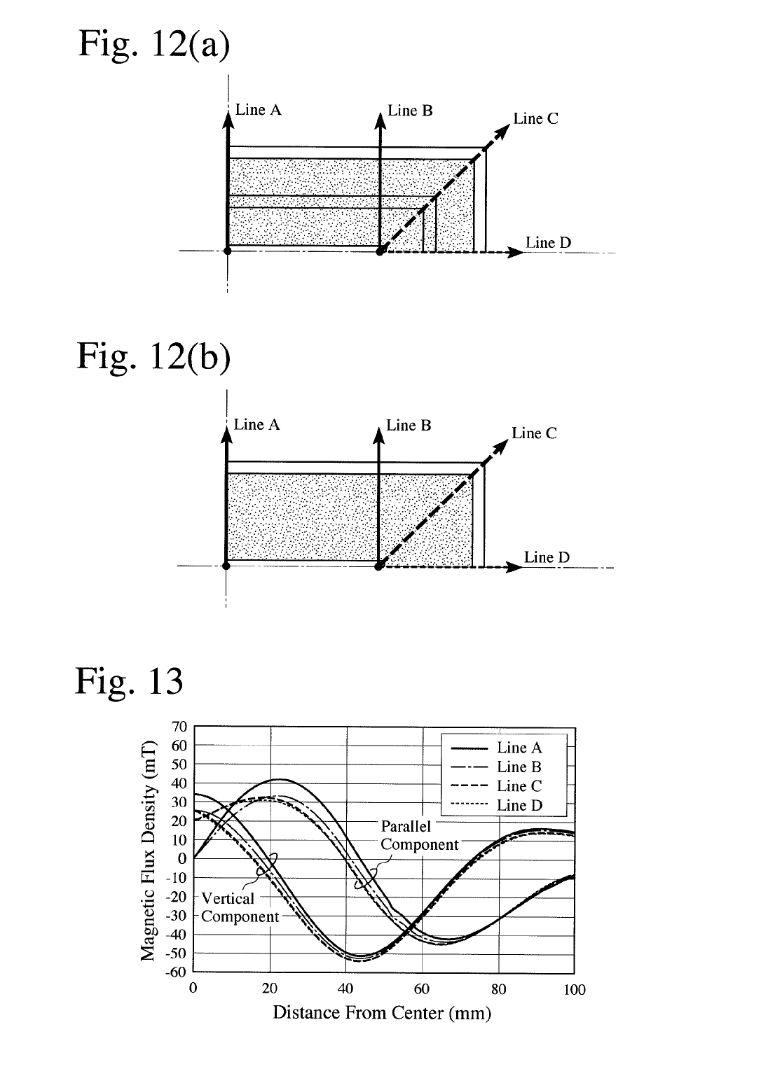

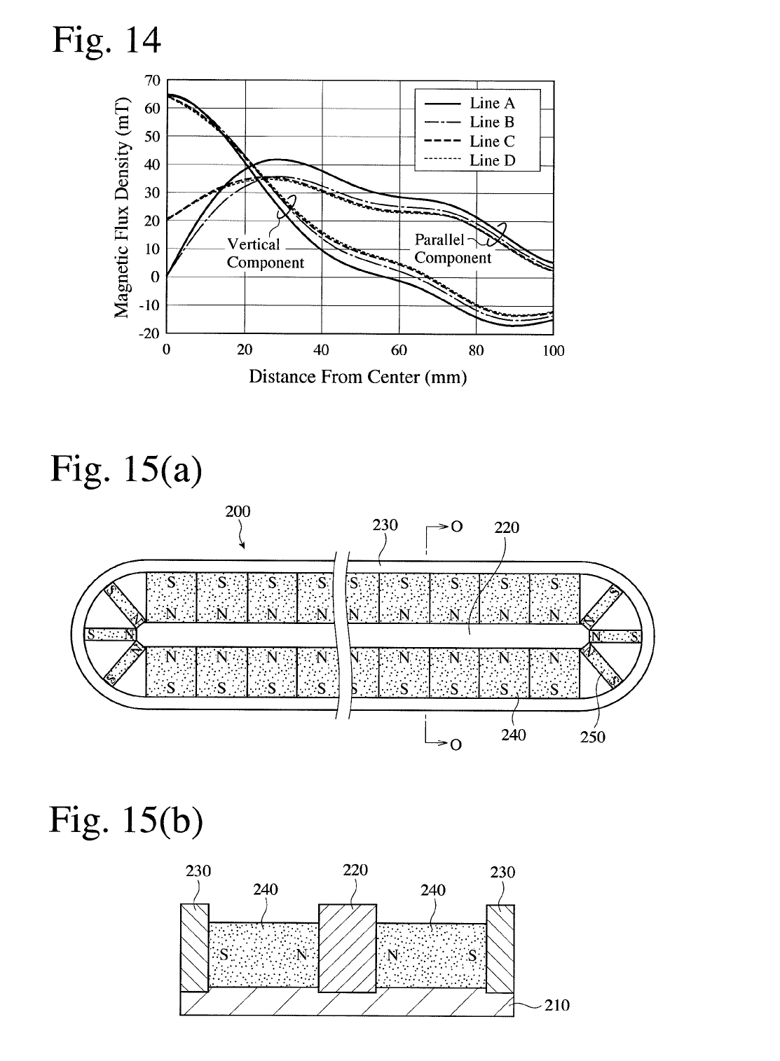

With respect to each magnetic-field-generating apparatus of Example 1 and Comparative Example 1, a magnetic flux density at a position 25 mm above its target-opposing surface (corresponding to a position of a target surface) was determined by magnetic field analysis. As shown in FIGS. 12(a) and 12(b), components of the magnetic flux density parallel and vertical to the target surface were determined along a line A (straight center portion), a line B (corner portion), a line C (corner portion) and a line D (corner portion), and plotted in FIG. 13 (Example 1) and FIG. 14 (Comparative Example 1).

FIGS. 13 and 14 indicate that with the permanent magnets 40 substituted by the permanent magnet units 4 in the straight portion, and the permanent magnets 50 substituted by the permanent magnet units 5 in the corner portions, a vertical magnetic flux density component was lowered in a portion opposing the center magnetic pole member 2 (about 0 mm distant from the center), indicating that a point at which the vertical magnetic flux density component was zero moved toward the center. It is expected from these results that the erosion of a target in a portion opposing the center magnetic pole member 2 is more accelerated in the magnetic-field-generating apparatus of the present invention (Example 1) than in the conventional apparatus (Comparative Example 1), so that the former provides higher use efficiency of the target.

### Effect of the Invention

The magnetic-field-generating apparatus of the present invention provides faster erosion of a target in a portion opposing a center magnetic pole member, resulting in more uniform erosion of the target, and thus higher use efficiency of the target. The magnetic-field-generating apparatus of the present invention makes unnecessary a mechanism for mechanically swinging the target or the magnetic-field-generating apparatus, thereby reducing the size of the apparatus, and thus providing cost reduction.

1. A magnetic-field-generating apparatus for magnetron sputtering having a racetrack shape comprising a straight portion and corner portions, and opposing a target for generating a magnetic field on a target surface, which comprises, on a non-magnetic base,
(a) a straight center magnetic pole member;
(b) a peripheral magnetic pole member surrounding said center magnetic pole member;
(c) pluralities of vertical permanent magnets arranged between said center magnetic pole member and said peripheral magnetic pole member, such that they surround said center magnetic pole member, with their magnetization directions perpendicular to said target surface;
(d) pluralities of first horizontal permanent magnets arranged between said center magnetic pole member and said vertical permanent magnets, their magnetic poles of the first polarity opposing said center magnetic pole member, and their magnetic poles of the second polarity opposing said vertical permanent magnets; and
(e) pluralities of second horizontal permanent magnets arranged between said peripheral magnetic pole member and said vertical permanent magnets, their magnetic poles of the first polarity opposing said peripheral magnetic pole member, and their magnetic poles of the second polarity opposing said vertical permanent magnets;
the magnetic poles of said first and second horizontal permanent magnets opposing said vertical permanent magnets being the same in polarity as those of said vertical permanent magnets opposing said target surface.

2. The magnetic-field-generating apparatus for magnetron sputtering according to claim 1, wherein the total length of said first and second horizontal permanent magnets in a magnetization direction is 50-95% of a gap between said center magnetic pole member and said peripheral magnetic pole member.

3. The magnetic-field-generating apparatus for magnetron sputtering according to claim 1, wherein said first and second horizontal permanent magnets have the same thickness in a direction perpendicular to said target surface, and wherein assuming that their thickness is 100, the thickness of said vertical permanent magnets is 0-150 in a direction perpendicular to said target surface.

4. The magnetic-field-generating apparatus for magnetron sputtering according to claim 1, wherein said vertical permanent magnets and said first and second horizontal permanent magnets in said corner portions are as thick as 30-100% in a direction perpendicular to said target surface, relative to said vertical permanent magnets and said first and second horizontal permanent magnets, respectively, in said straight portion.

5. The magnetic-field-generating apparatus for magnetron sputtering according to claim 4, wherein said second horizontal permanent magnets are thinner than said first horizontal permanent magnets in said corner portions in a direction perpendicular to said target surface.

6. The magnetic-field-generating apparatus for magnetron sputtering according to claim 1, wherein said vertical permanent magnets and said first and second horizontal permanent magnets occupy 30% or more by area of a gap between said center magnetic pole member and said peripheral magnetic pole member in said corner portions, when viewed from above.

7. The magnetic-field-generating apparatus for magnetron sputtering according to claim 6, wherein a gap between said center magnetic pole member and said peripheral magnetic pole member in each corner portion is filled with said vertical permanent magnets, said first and second horizontal permanent magnets, and non-magnetic spacers.

8. A magnetic-field-generating apparatus for magnetron sputtering having a structure obtained by removing part or all of end portions of said center magnetic pole member, said peripheral magnetic pole member and said vertical permanent magnets in said corner portions from the magnetic-field-generating apparatus recited in claim 1.

9. A magnetic-field-generating apparatus for magnetron sputtering having a racetrack shape comprising a straight portion and corner portions, and opposing a target for generating a magnetic field on a target surface, which comprises, on a non-magnetic base,
(a) a straight center magnetic pole member;
(b) a peripheral magnetic pole member surrounding said center magnetic pole member;
(c) an intermediate magnetic pole member arranged between said center magnetic pole member and said peripheral magnetic pole member, such that they surround said center magnetic pole member;
(d) pluralities of first horizontal permanent magnets arranged between said center magnetic pole member and said intermediate magnetic pole member, their magnetic poles of the first polarity opposing said center magnetic pole member, and their magnetic poles of the second polarity opposing said intermediate magnetic pole member; and
(e) pluralities of second horizontal permanent magnets arranged between said peripheral magnetic pole member and said intermediate magnetic pole member, their magnetic poles of the first polarity opposing said peripheral magnetic pole member, and their magnetic poles of the second polarity opposing said intermediate magnetic pole member;
the magnetic poles of said first and second horizontal permanent magnets opposing said intermediate magnetic pole member having the same polarity.

10. The magnetic-field-generating apparatus for magnetron sputtering according to claim 9, wherein said intermediate magnetic pole member has width, which is 10-75% of the thickness of said first and second horizontal permanent magnets in a direction perpendicular to said target surface.

11. The magnetic-field-generating apparatus for magnetron sputtering according to claim 9 or 10, wherein said first and second horizontal permanent magnets have the same thickness in a direction perpendicular to said target surface, and wherein assuming that their thickness is 100, the thickness of said intermediate magnetic pole member is 0-150 in a direction perpendicular to said target surface.

12. A magnetic-field-generating apparatus for magnetron sputtering having a structure obtained by removing part or all of end portions of said center magnetic pole member, said peripheral magnetic pole member and said intermediate magnetic pole member in said corner portions from the magnetic-field-generating apparatus recited in claim 9.

13. The magnetic-field-generating apparatus for magnetron sputtering according to claim 1, wherein when a magnetic field applied to said target surface is measured in a direction perpendicular to the axial direction in said straight portion, the maximum magnetic flux density in parallel to said target surface is larger than a magnetic flux density in a perpendicular direction to said target surface, in a region opposing said center magnetic pole member.

14. The magnetic-field-generating apparatus for magnetron sputtering according to claim 1, wherein at a position where a magnetic field applied to said target surface has a magnetic flux density of zero in a perpendicular direction to said target surface, a magnetic flux density in parallel to said target surface is 10 mT or more.

15. The magnetic-field-generating apparatus for magnetron sputtering according to claim 9, wherein when a magnetic field applied to said target surface is measured in a direction perpendicular to the axial direction in said straight portion, the maximum magnetic flux density in parallel to said target surface is larger than a magnetic flux density in a perpendicular direction to said target surface, in a region opposing said center magnetic pole member.

16. The magnetic-field-generating apparatus for magnetron sputtering according to claim 9, wherein at a position where a magnetic field applied to said target surface has a magnetic flux density of zero in a perpendicular direction to said target surface, a magnetic flux density in parallel to said target surface is 10 mT or more.
